(19) United States
(12) Patent Application Publication
(10) Pub. No.: US 2006/0172449 A1
(43) Pub. Date: Aug. 3, 2006

(54) Method for manufacturing semiconductor laser diode

(75) Inventor: Sang Bum Lee, Suwon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 11/220,117

(22) Filed: Sep. 6, 2005

(30) Foreign Application Priority Data
Nov. 18, 2004 (KR) 10-2004-0094699

(51) Int. Cl. H01L 21/00

(52) U.S. Cl. 438/46; 438/39; 438/22

(57) ABSTRACT

The present invention provides a semiconductor laser diode and a method for forming a semiconductor laser diode. After forming a first mask on a ridge structure forming region of a second conductivity type clad layer, ridge structure having vertical side surfaces is formed on an upper portion of the second conductivity type clad layer by dry etching the second conductivity type clad layer. Then After forming a second mask surrounding an upper surface and the vertical side surfaces of the ridge, a portion of the second conductivity type clad layer damaged during dry etching is removed by wet etching.

### RELATED APPLICATION

The present invention is based on, and claims priority from, Korean Application Number 2004-94699, filed Nov. 18, 2004, the disclosure of which is incorporated by reference herein in its entirety.

### BACKGROUND OF THE INVENTION

1. Field of the Invention

The present invention generally relates to a semiconductor laser diode, and, more particularly, to a method for manufacturing a semiconductor laser diode, which has a ridge structure with substantially vertical side surfaces at both sides thereof.

2. Description of the Related Art

Generally, a semiconductor laser diode can oscillate light having a narrow frequency width (monochromatic property) and a high directionality while ensuring high intensity, and thus it has various applications including optical communication, multi-communication, and space communication, as well as an optical source for an optical pick-up device of optical disk systems, such as CD, DVD and the like.

Modern semiconductor laser diodes employ a p-type clad layer having a selectively buried ridge (SBR) structure in order to enhance current injection efficiency and optical properties thereof. FIG. 1 shows one example of an AlGaInP-based semiconductor laser diode having a typical SBR structure.

As shown in FIG. 1, the semiconductor laser diode 10 comprises an n-type substrate 11, an n-type AlGaInP clad layer 12, an AlGaInP/GaInP-based active layer 13 having a multi-quantum well structure, a p-type AlGaInP clad layer 14, and a p-type GaAs cap layer 16 sequentially formed in this order from the bottom.

An upper portion of the p-type clad layer 14 is formed to have a ridge structure R. In order to allow the ridge structure R to be easily formed, the p-type clad layer 14 may further comprise an etching stop layer (not shown) between the upper portion of the p-type clad layer 14 having the ridge structure and a lower portion of the p-type clad layer 14.

The semiconductor laser diode 10 further comprises current blocking layers 17 formed at both sides of the ridge structure R, an n-electrode 19a formed under a lower surface of the n-type substrate 11, and a p-electrode 19b formed over the cap layer 16 and the current blocking layers 17.

Here, in the conventional semiconductor laser diode 10, since the ridge structure R is formed by wet etching, it has inclined side surfaces, as shown in FIG. 2a, and is formed to have a non-symmetrical structure according to a crystallographic direction. Additionally, an undercut shape is formed under the p-type cap layer due to an etching rate difference between the p-type cap layer and the p-type clad layer. Such a non-symmetrically inclined ridge structure has many disadvantages in comparison to a symmetrically vertical ridge structure as follows:

1. Due to a great difference in width between upper and lower portions of the ridge structure, it is difficult to increase the thickness of the p-type clad layer, and thus it is difficult to reduce optical loss towards the p-type cap layer;

2. It is difficult to form a narrow lower portion of the ridge appropriate for a single mode operation;

3. The undercut shape formed at the lower portion of the p-type cap layer causes connection failure at the side surfaces of the ridge structure, thereby forming a non-connection space A in which the p-type electrode (p-metal and bonding metal) is not formed at the side surfaces of the ridge structure;

4. It is difficult to control the laser beam spot size due to asymmetry of the ridge structure, and the like.

Of course, considering that the inclined ridge structure is caused by isotropic wet etching, and by the etching rate difference according to the crystallographic direction, the vertical ridge structure can be easily achieved by use of dry etching which permits anisotropic etching. Moreover, dry etching has advantages in that the vertical ridge structure can be advantageously realized by anisotropic dry etching, and in that etching depth and width can be easily controlled with excellent etching uniformity.

However, in spite of these advantages, dry etching causes a problem in that a crystallographic plane is significantly damaged by plasma used for dry etching. Defects formed on the damaged plane prohibit growth of an additional crystal layer in a subsequent process (when forming a CBM layer as a p-type GaAs layer) as well as significantly reducing electrical and optical properties.

As a result, regardless of its many disadvantages, the asymmetrical ridge structure having the inclined side surfaces is still employed for the semiconductor laser diode.

### SUMMARY OF THE INVENTION

The present invention has been made to solve the above problems, and it is an object of the present invention to provide a method for manufacturing a semiconductor laser diode, which can form a symmetrically vertical ridge structure while eliminating a damaged surface due to dry etching through a combination of dry etching and wet etching.

In accordance with one aspect of the present invention, the above and other objects can be accomplished by the provision of a method for manufacturing a semiconductor laser diode, comprising the steps of: sequentially forming a first conductivity type clad layer, an active layer, and a second conductivity type clad layer on a substrate; forming a first mask on a ridge structure forming region of the second conductivity type clad layer; forming a ridge structure having vertical side surfaces on an upper portion of the second conductivity type clad layer by dry etching the second conductivity type clad layer; forming a second mask surrounding an upper surface and the vertical side surfaces of the ridge structure; removing a portion of the second conductivity type clad layer damaged during dry etching by wet etching an upper surface of the second conductivity type clad layer; and forming a current blocking layer on the second conductivity type clad layer so as to expose the upper surface of the ridge structure.

An etchant used for the step of forming the ridge structure may be a Cl-based etchant. For example, the Cl-based etchant may be at least one selected from the group consisting of Cl₂, BCl₃, CCl₄ and SiCl₄.

The first and second masks may be formed of a dielectric material, and preferably, of SiO₂ or SiNₓ used for a typical semiconductor manufacturing process.

In this case, the step of forming the second mask may comprise forming an additional dielectric layer over the upper surface of the second conductivity type clad layer having the first mask present thereon, and dry etching the upper surface of the second conductivity type clad layer to a depth greater than a thickness of the additional dielectric layer while being less than a total thickness of the additional dielectric layer and the first mask.

The first mask may consist of a photoresist. In this case, the step of forming the second mask may comprise forming an additional dielectric layer over the upper surface of the second conductivity type clad layer having the first mask present thereon, and dry etching the upper surface of the second conductivity type clad layer to a depth corresponding to at least a thickness of the additional dielectric layer. At this time, the photoresist of the first mask and the dielectric layer formed on the side surfaces of the ridge structure may remain without being etched, and constitute the second mask.

In this case, an etchant used for the step of forming the second mask may be an F-based etchant. For example, the F-based etchant may be at least one selected from the group consisting of CF₄, C₃F₆, SF₆ and CHF₃.

The method may further comprise the step of: forming a second conductivity type cap layer on the second conductivity type upper-clad layer before the step of forming the first mask, the step of forming the first mask may be the step of forming the first mask on the ridge structure forming region of the second conductivity type cap layer, and the step of forming the ridge structure may comprise dry etching the second conductivity type upper-clad layer and the second conductivity type cap layer. In this case, the step of forming the second conductivity type clad layer may comprise forming a second conductivity type lower-clad layer on the active layer, forming an etching stop layer on the second conductivity type lower-clad layer, and forming a second conductivity type upper-clad layer on the etching stop layer.

In the step of forming the ridge structure, the second conductivity type upper-clad layer is dry-etched such that the second conductivity type upper-clad layer remains to have a predetermined depth at both sides of the ridge structure. In this case, in order to obtain a substantially vertical ridge, the second conductivity type upper-clad layer remaining after dry etching may have a thickness 50% or less of a thickness of the second conductivity type upper-clad layer before dry etching, and more preferably in the range of 1 to 20% of that of the second conductivity type upper-clad layer before dry etching.

The step of removing the damaged portion of the second clad layer may be the step of wet etching the second conductivity type upper-clad layer at both sides of the ridge structure by use of the etching stop layer.

### BRIEF DESCRIPTION OF THE DRAWINGS

The foregoing and other objects and features of the present invention will be more clearly understood from the following detailed description taken in conjunction with the accompanying drawings, in which:

FIG. 1 is a perspective view of a conventional semiconductor laser diode;

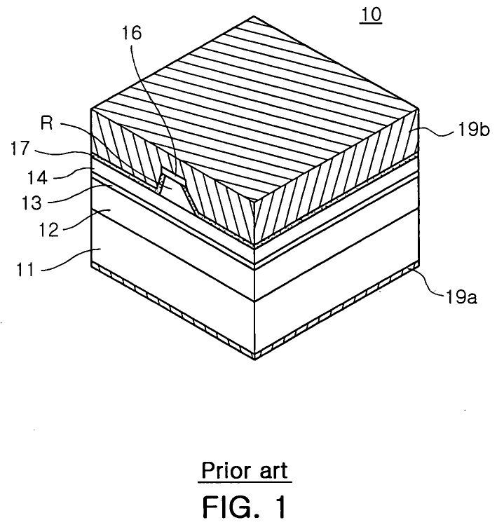

FIGS. 2a and 2b are SEMs showing ridge structures of the conventional semiconductor laser diode;

FIGS. 3a to 3h are step diagrams illustrating a method for manufacturing a semiconductor laser diode in accordance with the present invention;

FIGS. 4a and 4b are perspective views of a semiconductor laser diode manufactured according to the method of the present invention; and

FIGS. 5a and 5b are SEMs showing ridge structures of the semiconductor laser diode manufactured according to the method of the present invention.

### DESCRIPTION OF THE PREFERRED EMBODIMENTS

Preferred embodiments will now be described in detail with reference to the accompanying drawings.

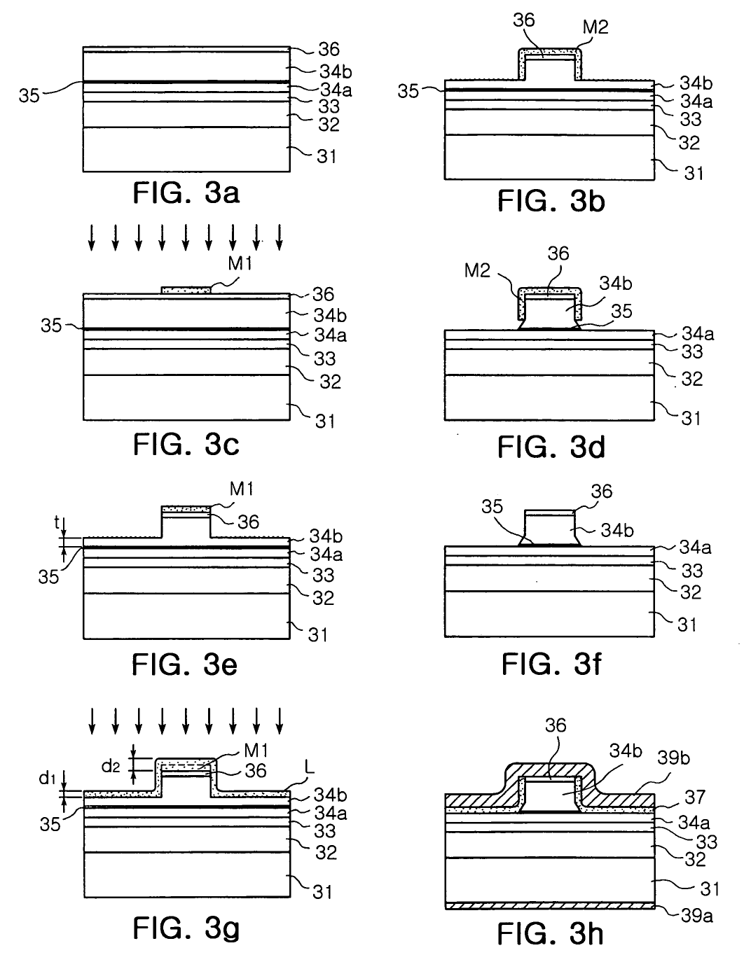

FIGS. 3a and 3b are step diagrams illustrating a method for manufacturing a semiconductor laser diode in accordance with the present invention.

First, as shown in FIG. 3a, a first conductivity type AlGaInP-based clad layer 32, an AlGaInP-based active layer 33, and a second conductivity type AlGaInP-based clad layer 34 are sequentially formed upon a first conductivity type GaAs substrate 31. A buffer layer (not shown) may be additionally formed on an upper surface of the first conductivity type GaAs substrate 31 in order to relieve lattice mismatch. The second conductivity type clad layer 34 may comprise an etching stop layer 35, which is composed of a material having a lower etching rate in order to form a ridge structure. The second conductivity type clad layer 34 may consist of a second conductivity type lower-clad layer 34a and a second conductivity type upper-clad layer 34a which will be formed into the ridge structure. Moreover, a second conductivity type InGaP cap layer 36 may be formed on the second conductivity type upper-clad layer 34b.

Then, as shown in FIG. 3b, a first mask M1 is formed on a ridge structure forming region on an upper surface of the second conductivity type InGaP cap layer 36, and the second conductivity type clad layer 34 (in the present embodiment, the second conductivity type upper-clad layer 34b) is subjected to selective dry etching for forming the ridge structure. In the present embodiment, the first mask M1 is formed of a dielectric material, such as SiO₂ or SiN. Alternatively, the first mask M1 may consist of a photoresist, which will be described below.

An etching process for forming the ridge structure may be performed by means of a plasma etching process, and as an etchant used for forming the ridge structure, a Cl-based etchant is preferably used. For example, the Cl-based etchant may be at least one selected from the group consisting of Cl₂, BCl₃, CCl₄ and SiCl₄.

As a result of dry etching as shown in FIG. 3b, the second conductivity type upper-clad layer 34b is formed to have a vertical ridge structure as shown in FIG. 3c. Since dry etching for forming the vertical ridge structure is anisotropic, the ridge formed by the dry etching has vertical side surfaces at both sides thereof. In this case, a dry etching depth is preferably set to allow the second conductivity type upper-clad layer 34b to remain in a predetermined thickness t at both sides of the ridge. Preferably, the thickness t of the second conductivity type upper-clad layer 34b remaining after dry etching is 50% or less than a thickness of the second conductivity type upper-clad layer 34b before dry etching in order to form a substantially vertical ridge structure, and more preferably, in the range of 5˜20% thereof. If the thickness t of the second conductivity type upper-clad layer 34b remaining after dry etching is less than 1%, it may be difficult for a subsequent process to completely remove a damaged portion of the second conductivity type upper-clad layer 34b due to dry etching.

As described above, a dry-etched surface of the second conductivity type upper-clad layer 34b can be significantly damaged by the plasma used for dry etching. Accordingly, it is necessary to remove the damaged portion of the conductivity type upper-clad layer 34b. For a process for removing the damaged portion, the invention provides an additional dielectric mask having an appropriate shape. The additional dielectric mask proposed by the invention has a shape surrounding an upper surface and the side surfaces of the ridge. The process for forming such a mask is illustrated in FIGS. 3d and 3e.

As shown in FIG. 3d, with the first dielectric mask M1 remaining on the second conductivity type cap layer 36, an additional dielectric layer L having a predetermined thickness d₁ is formed. The dielectric layer L may be formed of SiO₂ or SiNₓ, and alternatively, may be formed of the same material as that of the first dielectric mask M1. As a result, a thickness d₂ of the dielectric material on the second conductivity type cap layer 36, which corresponds to an upper surface of the ridge structure, is the same as a total thickness of the additional dielectric layer L and the first dielectric mask M1, and a thickness d₁ of the dielectric material on the upper surface of the dry-etched second conductivity type upper-clad layer 34b is the same as the thickness d₁ of the additional dielectric layer L. The dielectric material is dry-etched to a depth greater than the thickness d₁ of the dielectric layer L and less than the total thickness d₂ of the first dielectric mask Ml and the additional dielectric layer M2. As an etchant used for forming the second dielectric mask M2, an F-based etchant may be used. For example, the F-based etchant may be at least one selected from the group consisting of CF₄, C₃F₆, SF₆ and CHF₃.

In this step, when the first mask M1 is formed of the photoresist, the additional dielectric layer is formed over the entirety of the upper surface of the photoresist, and is then dry-etched corresponding to the thickness of the photoresist, whereby the second mask M2 can be formed.

As a result of the process as shown in FIG. 3d, the dielectric layer L formed on the second conductivity type clad layer 34d can be completely removed such that the damaged surface of the second conductivity type clad layer 34d is exposed, and the second mask M2 surrounding the upper surface and the side surfaces of the desired ridge can be formed. The upper surface of the ridge of the second mask M2 may be the first mask M1 or a portion of the first mask M1. The second mask M2 formed as described above serves as a protective mask for protecting the vertical ridge structure formed by the primary dry etching process.

As described above, when the first mask M1 is composed of the photoresist, the second mask M2 may be composed of the photoresist at the upper surface of the ridge, and of the dielectric material at the side surfaces of the ridge.

As shown in FIG. 3e, wet etching is performed to remove the damaged surface of the second conductivity type upper-clad layer 34b. Since wet etching applied to this step is isotropic as described above, although it can influence other portions including the damaged surface desired to be removed, the vertical ridge structure can be protected by the second dielectric mask M2. Moreover, in the present embodiment, since some portion of the second upper-clad layer 34b remains, wet etching may be performed to an appropriate depth by use of the etching stop layer 35. An etchant used for wet etching of the invention may be an EG-based etchant.

Then, the second dielectric mask M2 is removed. Consequently, as shown in FIG. 3g, the second conductivity type upper-clad layer 34b is formed into a final ridge structure. The second conductivity type upper-clad layer 34b having the ridge structure comprises a vertical upper ridge region formed through dry etching and a slightly slanted lower ridge region formed through wet etching. Since a desirable structure of the ridge is a vertical structure, the vertical ridge structure may be formed to the maximum height possible by appropriately choosing the dry etching depth as described above under the condition of allowing the damaged portion of the second conductivity type upper-clad layer 34b by dry etching to be effectively removed.

Finally, as shown in FIG. 3f, a current blocking layer 37 is formed around the ridge structure, followed by forming first and second electrodes 39a and 39b under a lower surface of the substrate 31 and on the second conductivity type cap layer 36, respectively. Although the current blocking layer 37 is illustrated as being formed of the electrically insulating dielectric material, it may be formed of a first conductivity type semiconductor material.

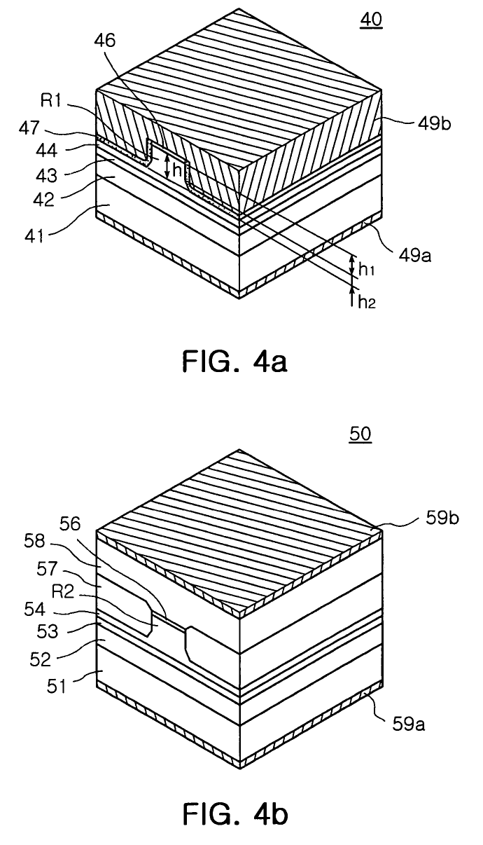

FIGS. 4a and 4b are perspective views of a semiconductor laser diode manufactured according to the method of the invention.

Referring to FIG. 4a, the semiconductor laser diode 40 comprises a first conductivity type GaAs substrate 41 having a first electrode 49a formed under the bottom thereof. A first conductivity type clad layer 42, an undoped active layer 43 having a multi-quantum well structure, and a second conductivity type clad layer 44 are sequentially formed in this order on the substrate 41. The second conductivity type clad layer 44 is formed to have a ridge structure by use of an etching stop layer 45 formed in a predetermined depth of the second conductivity type clad layer 44.

Moreover, the second conductivity type clad layer 44 may comprise a typical second conductivity type cap layer 46 formed on the ridge structure of the second conductivity type clad layer 44. A current blocking layer 47 composed of the dielectric material is formed around the ridge structure, and a second electrode 49b is formed on the second conductivity type cap layer 46 and the current blocking layer 47.

As shown in FIG. 4a, the ridge structure of the second conductivity type clad layer 44 comprises an upper ridge region having vertical side surfaces, and a slightly slanted lower ridge region. The upper ridge region having the vertical side surfaces is formed through a dry etching process, and the slightly slanted lower ridge region is formed through a wet etching process. A height hi of the upper ridge region is preferably about 50% or more of a total height h of the ridge structure, and more preferably about 80˜99% thereof. In other words, since the portion of the second conductivity type clad layer 44 damaged during the dry etching process must be completely removed, a height h₂ of the lower ridge region is preferably about 1% or more of the total height h of the ridge structure.

FIG. 4b illustrates a semiconductor laser diode 50 having a similar structure to that of the semiconductor laser diode 50 shown in FIG. 4a aside from the modified structure of the current blocking layer. Such structure of the semiconductor laser diode 50 may be easily realized by modifying the step of forming the current blocking region shown in FIG. 3h among the steps shown in FIGS. 3a to 4h.

Referring to FIG. 4b, the semiconductor laser diode 50 comprises a first conductivity type GaAs substrate 51 having a first electrode 59a formed under the bottom thereof. A first conductivity type clad layer 52, an active layer 53 having a multi-quantum well structure, and a second conductivity type clad layer 54 are sequentially formed on the substrate 51. The second conductivity type clad layer 54 is formed to have a ridge structure by use of an etching stop layer 55 formed in a predetermined depth of the second conductivity type clad layer 54.

Moreover, the second conductivity type clad layer 54 may comprise a typical second conductivity type cap layer 56 formed on the ridge structure of the second conductivity type clad layer 54. A current blocking layer 57 is formed around the ridge structure, and a second conductivity type contact layer 58 and a second electrode 59b are formed on the second conductivity type cap layer 56 and the current blocking layer 57.

Similar to the structure shown in FIG. 4a, the ridge structure of the second conductivity type clad layer 44 as shown in FIG. 4b comprises an upper ridge region having vertical side surfaces, and a slightly slanted lower ridge region. As a result, a width difference between the upper and lower ridge regions can be significantly reduced, and a substantially symmetrical ridge structure can be formed.

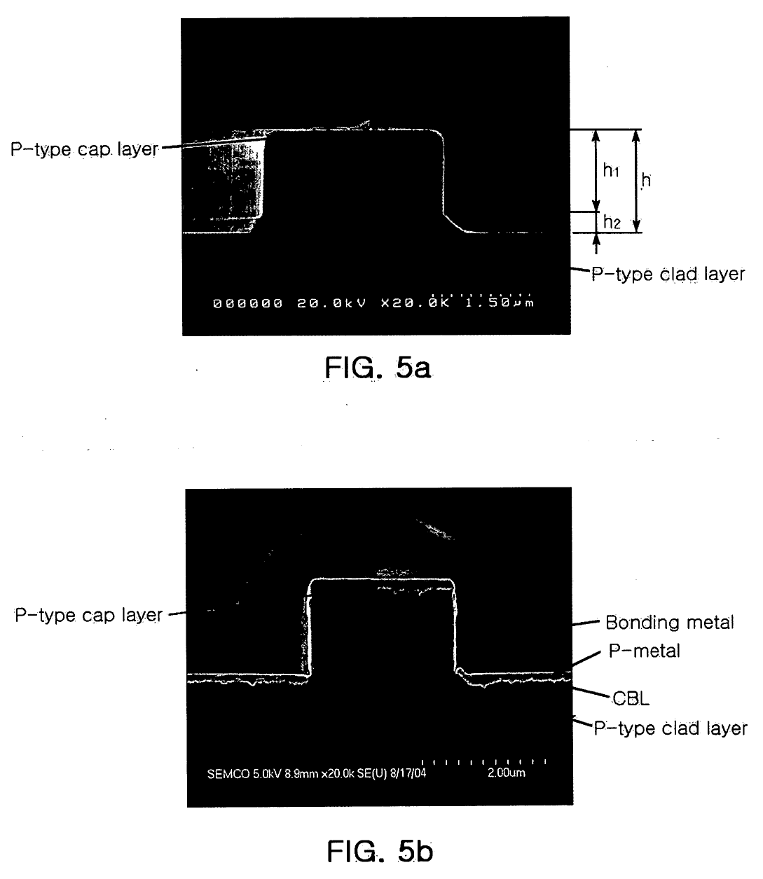

Referring to FIGS. 5a and 5b, aspects and effects of the ridge structure of the invention will be more easily understood.

FIG. 5a is an SEM showing a cross-sectional area of a final ridge structure formed by removing the second mask shown in FIG. 3g.

Referring to FIG. 5a, the ridge structure formed on a p-type conductivity type clad layer comprises an upper ridge region having vertical side surfaces, and a slightly slanted lower ridge region. The upper ridge region having the vertical side surfaces is formed by dry etching, and the slightly slanted lower ridge region is formed by wet etching. Moreover, the slanted lower ridge region corresponding to a portion of a total height of the ridge structure is formed by wet etching for removing the surface damaged during the dry etching process, and is preferably set as thin as possible under the condition of allowing the damaged surface of the second conductivity type clad layer to be effectively removed. Additionally, in FIG. 5a, since a height hi of the upper ridge region having the vertical side surfaces is about 85% of the total height h of the ridge structure, and a height h₂ of the lower ridge region is 15% of the total height h of the ridge structure, the ridge structure is substantially symmetrical, and can provide effects similar to those of the ridge structure having the substantially vertical side surfaces.

That is, with the structure as described above, since a width difference between the upper and lower ridge regions can be significantly reduced, the thickness of the p-type clad layer may be sufficiently increased so as to reduce optical loss into the second conductivity type cap layer, and the structure as described above is advantageous to realize a narrow lower ridge region appropriate for a single mode operation. Moreover, the substantially symmetrical shape of the ridge structure advantageously permits accurate control over laser spot size.

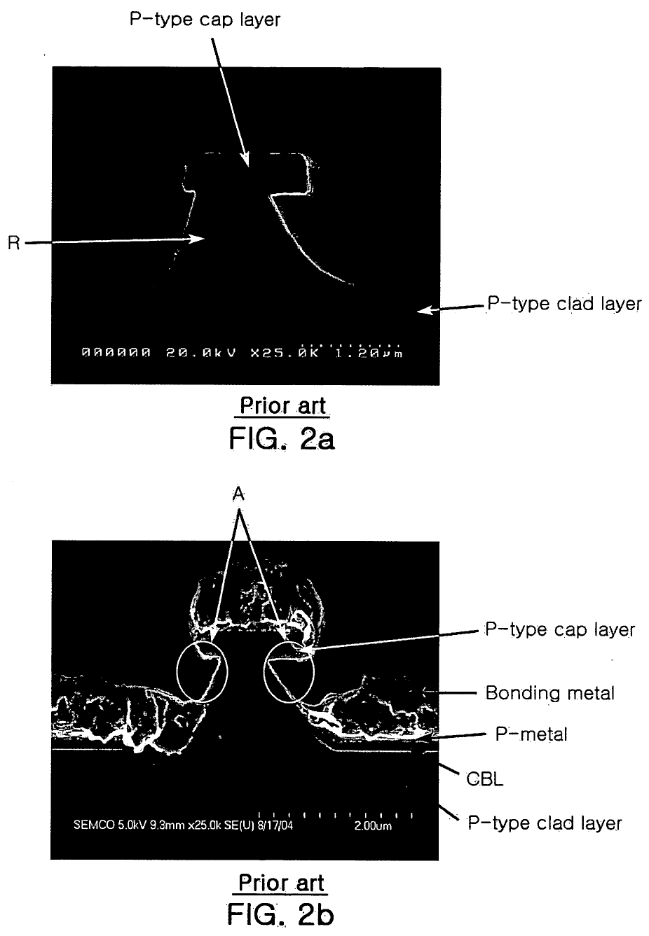

Moreover, as shown in FIG. 5b, when forming a p-metal and a bonding metal in order to form a p-side electrode, since the second conductivity type cap layer is also etched to the same width as that of the second conductivity type clad layer and provides the vertical side surfaces, undercut is not formed, and unlike the structure shown in FIG. 2b, an electrode having a uniform thickness can be formed over the entire surface. Accordingly, the problem of connection failure caused by the undercut structure can be effectively solved.

As apparent from the above description, according to the method of the invention, dry etching and wet etching are effectively combined when manufacturing the semiconductor laser diode, thereby forming the symmetrical ridge having the desired vertical side surfaces, and simultaneously removing the surface damaged during dry etching. Accordingly, the thickness of the p-type clad layer can be sufficiently increased so as to reduce the optical loss into the second conductivity type cap layer, the ridge structure is advantageous to realize the narrow lower ridge region appropriate for the single mode operation, and the problem of connection failure caused by an undercut shape can be effectively solved.

It should be noted that although the method of the invention has been described as a method for manufacturing the AlGaInP-based semiconductor laser diode as an example of the invention, the present invention is not limited thereto, and the method of the invention can be similarly applied to a method for manufacturing an AlGaAs-based or AlGaInN-based semiconductor laser diode to have the ridge structure as described above.

It should be understood that the embodiments and the accompanying drawings have been described for illustrative purposes and the present invention is limited by the following claims. Further, those skilled in the art will appreciate that various modifications, additions and substitutions are allowed without departing from the scope and spirit of the invention as set forth in the accompanying claims.

What is claimed is:

1. A method for manufacturing a semiconductor laser diode, comprising the steps of:
sequentially forming a first conductivity type clad layer, an active layer, and a second conductivity type clad layer on a substrate;
forming a first mask on a ridge structure forming region of the second conductivity type clad layer;
forming a ridge structure having vertical side surfaces on an upper portion of the second conductivity type clad layer by dry etching the second conductivity type clad layer;
forming a second mask surrounding an upper surface and the vertical side surfaces of the ridge structure;
removing a portion of the second conductivity type clad layer damaged during dry etching by wet etching an upper surface of the second conductivity type clad layer; and
forming a current blocking layer on the second conductivity type clad layer so as to expose the upper surface of the ridge structure.

2. The method as set forth in claim 1, wherein an etchant used for the step of forming the ridge structure is a Cl-based etchant.

3. The method as set forth in claim 2, wherein the Cl-based etchant is at least one selected from the group consisting of Cl₂, BCl₃, CCl₄ and SiCl₄.

4. The method as set forth in claim 1, wherein the first and second masks are formed of a dielectric material.

5. The method as set forth in claim 4, wherein the dielectric material is SiO₂ or SiNₓ.

6. The method as set forth in claim 4, wherein the step of forming the second mask comprises:
forming an additional dielectric layer over the upper surface of the second conductivity type clad layer having the first mask present therein, the first mask being formed of the dielectric material; and
dry etching the upper surface of the second conductivity type clad layer to a depth greater than a thickness of the additional dielectric layer while being less than a total thickness of the additional dielectric layer and the first mask.

7. The method as set forth in claim 6, wherein an etchant used for the step of forming the second mask is an F-based etchant.

8. The method as set forth in claim 7, wherein the F-based etchant is at least one selected from the group consisting of CF₄, C₃F₆, SF₆ and CHF₃.

9. The method as set forth in claim 1, wherein the first mask is a photoresist.

10. The method as set forth in claim 9, wherein the step of forming the second mask comprises:
forming an additional dielectric layer over the upper surface of the second conductivity type clad layer having the first mask present therein; and
dry etching the upper surface of the second conductivity type clad layer to a depth corresponding to at least a thickness of the additional dielectric layer.

11. The method as set forth in claim 10, wherein an etchant used for the step of forming the second mask is an F-based etchant.

12. The method as set forth in claim 11, wherein the F-based etchant is at least one selected from the group consisting of CF₄, C₃F₆, SF₆ and CHF₃.

13. The method as set forth in claim 1, wherein the step of forming the second conductivity type clad layer comprises:
forming a second conductivity type lower-clad layer on the active layer;
forming an etching stop layer on the second conductivity type lower-clad layer; and
forming a second conductivity type upper-clad layer on the etching stop layer.

14. The method as set forth in claim 13, wherein the method further comprises the step of:
forming a second conductivity type cap layer on the second conductivity type upper-clad layer before the step of forming the first mask, the step of forming the first mask being the step of forming the first mask on the ridge structure forming region of the second conductivity type cap layer, and the step of forming the ridge structure comprises dry etching the second conductivity type upper-clad layer and the second conductivity type cap layer.

15. The method as set forth in claim 14, wherein in the step of forming the ridge structure, the second conductivity type upper-clad layer is dry-etched such that the second conductivity type upper-clad layer remains to have a predetermined depth at both sides of the ridge structure.

16. The method as set forth in claim 15, wherein the second conductivity type upper-clad layer remaining after dry etching has a thickness 50% or less of a thickness of the second conductivity type upper-clad layer before dry etching.

17. The method as set forth in claim 15, wherein the second conductivity type upper-clad layer remaining after dry etching has a thickness in the range of 1 to 20% of a thickness of the second conductivity type upper-clad layer before dry etching.

18. The method as set forth in claim 12, wherein the step of removing the damaged portion of the second clad layer is the step of wet etching the second conductivity type upper-clad layer at both sides of the ridge structure by use of the etching stop layer.

19. The method as set forth in claim 1, wherein the current blocking layer is an electrically insulating dielectric layer.

20. The method as set forth in claim 1, wherein the current blocking layer is a first conductivity type semiconductor layer.
